(19) United States
(12) Patent Application Publication
(10) Pub. No.: US 2022/0093187 A1
(43) Pub. Date: Mar. 24, 2022

(54) MEMORY SYSTEM AND CONTROL METHOD

(71) Applicant: Kioxia Corporation, Tokyo (JP)

(72) Inventors: Rintaro IMAMURA, Zama Kanagawa (JP); Hayato MASUBUCHI, Ome Tokyo (JP)

(73) Assignee: Kioxia Corporation, Tokyo (JP)

(21) Appl. No.: 17/464,898

(22) Filed: Sep. 2, 2021

(30) Foreign Application Priority Data
Sep. 18, 2020 (JP) 2020-157673

(51) Int. Cl. G11C 16/30; G11C 16/34

(52) U.S. Cl. CPC G11C 16/30; G11C 16/3418

(57) ABSTRACT

A memory system according to at least one embodiment includes a semiconductor storage device and a controller. The semiconductor storage device includes an output transistor and a circuit for changing a magnitude of a current of the output transistor. The controller receives a signal output from the semiconductor storage device via the output transistor, and controls the circuit based on a level of the received signal.

### CROSS-REFERENCE TO RELATED APPLICATION

This application is based upon and claims the benefit of priority from Japanese Patent Application No. 2020-157673, filed Sep. 18, 2020, the entire contents of which are incorporated herein by reference.

### FIELD

Embodiments described herein relate generally to a memory system and a control method.

### BACKGROUND

A semiconductor integrated circuit in which a duty ratio of a signal to be transmitted is adjustable is known. It is expected that a quality of the signal transmitted by the semiconductor integrated circuit, the quality including rising and falling timings, will be improved.

### DESCRIPTION OF THE DRAWINGS

FIG. 1 is a block diagram illustrating a configuration of a memory system according to at least one embodiment.

FIG. 2 is a diagram illustrating a first example of a configuration of a drive strength switching circuit according to at least one embodiment.

FIG. 3 is a diagram illustrating a second example of a configuration of the drive strength switching circuit according to at least one embodiment.

FIG. 4 is a diagram illustrating a third example of a configuration of the drive strength switching circuit according to at least one embodiment.

FIG. 5 is a block diagram illustrating a configuration of a NAND PHY according to at least one embodiment.

FIG. 6 is a diagram illustrating a configuration of a control circuit according to at least one embodiment.

FIG. 7 is a timing chart illustrating an example of an operation of the memory system according to at least one embodiment.

FIG. 8 is a diagram illustrating an example of a read DQS and a read DQ received by a reception unit from a signal reception circuit according to at least one embodiment.

FIG. 9 illustrates an example of waveforms of the read DQS and the read DQ according to at least one embodiment.

FIG. 10 is a diagram illustrating a processing flow of the memory system according to at least one embodiment.

FIG. 11 is a block diagram illustrating a configuration of a memory system according to a first modification example.

FIG. 12 is a block diagram illustrating a configuration of a memory system according to a second modification example.

### DETAILED DESCRIPTION

Embodiments provide a memory system and a control method capable of improving a quality of a signal.

In general, according to at least one embodiment, there is provided a memory system including a semiconductor storage device and a controller. The semiconductor storage device includes an output transistor and a circuit for changing a magnitude of a current of the output transistor. The controller receives a signal output from the semiconductor storage device via the output transistor, and controls the circuit based on a level of the received signal.

Hereinafter, a memory system and a control method according to at least one embodiment will be described with reference to drawings. In the following description, configurations having the same or substantially the same functions are designated by the same reference numerals. Duplicate description of those configurations may be omitted. In the present specification, a term of “based on XX” means “based on at least XX” and includes a case of being based on another element in addition to XX. The term of “based on XX” is not limited to when XX is used directly, but also includes a case where a calculation or a process is performed with respect to XX. “XX” is any element (for example, any information).

In the present specification, “reading” may be referred to as “read”, and “writing” may be referred to as “write”. Further, in the present specification, “write”, “store”, and “save” are used in the same means as each other. Therefore, these terms are interchangeable. In the present specification, a term of “connection” is not limited to a mechanical connection but includes an electrical connection. In the present specification, “acquisition” is not limited to a case of obtaining information from the outside, but also includes a case of calculating in person.

The memory system includes a NAND device and a memory controller that controls the NAND device. A NAND PHY, which is a circuit in the memory controller, is configured to be able to correct a duty and a phase of a signal transmitted from the memory controller to the NAND device. The “phase” corresponds to a timing of rising (or falling) of an edge of a pulsed signal.

When reading data in the memory system, a plurality of signals corresponding to respective bits are output from the NAND device in parallel to the memory controller via a plurality of wires. In this case, conditions such as wiring to the memory controller to which each signal is transferred differ depending on a position of each semiconductor element storing data corresponding to each bit, in the NAND device. That is, load conditions for each semiconductor element differ according to a position of each semiconductor device that outputs each signal in the NAND device. As a result, timings of the plurality of signals received by the memory controller in parallel from the NAND device have variations.

Therefore, the memory system according to at least one embodiment adjusts an output current of the semiconductor element that outputs each signal in the NAND device when reading data. As a result, an output impedance of the NAND device may be changed, and the timing of the signal received by the controller is changed. Therefore, it is possible to reduce variations of the timings of the plurality of signals received by the memory controller from the NAND device in parallel. Hereinafter, such a memory system will be described. Meanwhile, the present disclosure is not limited to the embodiments, which will be described below.

### Embodiment

### Overall Configuration of Memory System

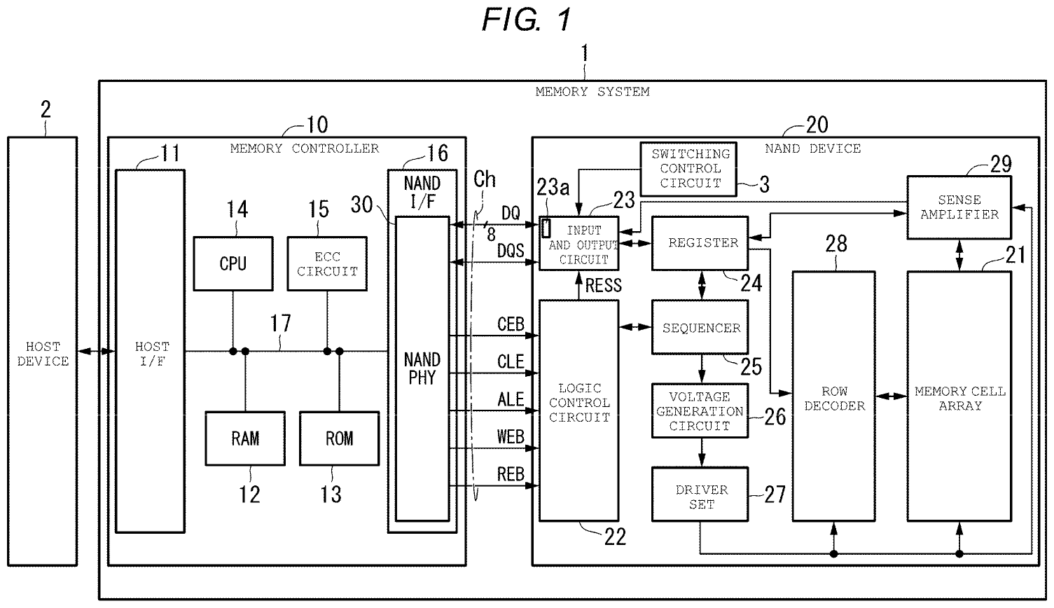

FIG. 1 is a block diagram illustrating a configuration of a memory system 1 according to at least one embodiment. The memory system 1 is, for example, one storage device, and is connectable to a host device 2. The memory system 1 functions as an external storage device of the host device 2. The host device 2 is a device that controls the memory system 1 in, for example, a server device, a personal computer, or a mobile information processing device. The host device 2 may issue an access request (a read request and/or a write request) to the memory system 1.

The memory system 1 includes, for example, a memory controller 10 and a plurality of NAND devices 20 (only one is illustrated in FIG. 1). The memory controller 10 is an example of a “controller”. Each NAND device 20 is an example of a “semiconductor storage device”.

### Memory Controller Configuration

The memory controller 10 includes, for example, a host interface circuit (a host I/F) 11, a random access memory (RAM) 12, a read only memory (ROM) 13, a central processing unit (CPU) 14, and an error correcting code (ECC) circuit 15, and a NAND interface circuit (NAND I/F) 16. The host I/F 11, the RAM 12, the ROM 13, the CPU 14, the ECC circuit 15, and the NAND I/F 16 in the memory controller 10 are connected to each other by a bus 17. For example, the memory controller 10 is configured with a system on a chip (SoC) in which the host I/F 11, the RAM 12, the ROM 13, the CPU 14, the ECC circuit 15, and the NAND I/F 16 are integrated into one chip. Meanwhile, some of these configurations may be provided outside the memory controller 10. One or more of the RAM 12, the ROM 13, the CPU 14, and the ECC circuit 15 may be provided inside the NAND I/F 16.

Under control of the CPU 14, the host I/F 11 controls a communication interface between the host device 2 and the memory system 1, and controls data transfer between the host device 2 and the RAM 12.

The RAM 12 is, for example, a synchronous dynamic random access memory (SDRAM) or a static random access memory (SRAM), and is not limited thereto. The RAM 12 functions as a buffer for data transfer between the host device 2 and the NAND device 20. The RAM 12 provides the CPU 14 with a work area. A firmware (a program) stored in the ROM 13 is loaded into the RAM 12 when the memory system 1 operates.

The CPU 14 is an example of a hardware processor. The CPU 14 controls an operation of the memory controller 10 by executing the firmware loaded in the RAM 12, for example. For example, the CPU 14 controls operations related to writing, reading, and erasing of data to the NAND device 20.

The ECC circuit 15 performs encoding for error correction with respect to write target data to the NAND device 20. When data read from the NAND device 20 includes an error, the ECC circuit 15 executes error correction with respect to the read data based on an error correction code given during a write operation.

The NAND I/F 16 executes control of data transfer between the RAM 12 and the NAND device 20, under control of the CPU 14. In at least one embodiment, the NAND I/F 16 has a plurality of channels Ch (only one is illustrated in FIG. 1). The NAND I/F 16 includes, for example, a plurality of NAND PHYs 30 in accordance with the number of channels Ch.

The NAND PHY 30 is a physical layer which is a part of a transmission and reception circuit of the NAND I/F 16. The NAND PHY 30 converts a digital signal transmitted from the memory controller 10 to the NAND device 20 into an electrical signal. The NAND PHY 30 transmits the converted electrical signal to the NAND device 20 through a transmission line L between the memory controller 10 and the NAND device 20 (only a part of the transmission line L is illustrated in FIG. 1). The NAND PHY 30 receives the electrical signal transmitted from the NAND device 20 through the transmission line L. The transmission line L may be provided as a differential transmission line. The NAND PHY 30 converts the received electrical signal into a digital signal. Details of the internal configuration of NAND PHY 30 will be described below. The NAND PHY 30 is an example of a “semiconductor integrated circuit”.

As illustrated in FIG. 1, the signal communicated between the NAND PHY 30 and the NAND device 20 includes a data signal (DQ), a data strobe signal (DQS), a chip enable signal (CEB), a command latch enable signal (CLE), an address latch enable signal (ALE), a write enable signal (WEB), a read enable signal (REB), a write protect signal (WP) (not illustrated), and the like. These signals are communicated via individual transmission lines L. The data signal (DQ) may be provided as a signal transmitted in parallel. Each of the data strobe signal (DQS), the write enable signal (WEB), and read enable signal (REB) may be a differential signal.

The data signal (DQ) includes a signal indicating contents of the write target data to the NAND device 20 (hereinafter, referred to as “write data”), a signal indicating contents of target data read from the NAND device 20 (hereinafter, referred to as “read data”), signals indicating various commands, a signal indicating an address of a data write destination or a data read destination, for example. The data signal (DQ) is communicated via eight transmission lines L independent from each other, for example, in units of 8 bits. In at least one embodiment, the write data and the read data, which are the data signals (DQ), may be respectively referred to as “write DQ” and “read DQ”.

The data strobe signal (DQS) is a strobe signal corresponding to the data signal (DQ). The data strobe signal (DQS) includes a write data strobe signal (hereinafter, referred to as “write DQS”) corresponding to the write DQ and a read data strobe signal (hereinafter referred to as “read DQS”) corresponding to the read DQ.

The write DQS is output from the NAND PHY 30 to the NAND device 20 together with the write DQ, and is used for reading the write data in the NAND device 20. The write DQS is a signal output according to an output of the write DQ, and includes a toggle signal (a signal in which a “Low” (“L”) level and a “High” (“H”) level are alternately repeated).

The read DQS is output from the NAND device 20 to the NAND PRY 30 together with the read DQ, and is used for reading the read data in the NAND PRY 30. The read DQS is a signal output according to an output of the read DQ, and includes a toggle signal. In at least one embodiment, the read DQS is generated in the NAND device 20 based on a source oscillation signal (a read data strobe source oscillation signal) output from the NAND PHY 30 to the NAND device 20, and is output from the NAND device 20 to the NAND PHY 30. This will be described below.

The chip enable signal (CEB) enables selection of the NAND device 20 to be accessed among the plurality of NAND devices 20, and is asserted when the NAND device 20 to be accessed is selected. The chip enable signal (CEB) is an active “L” signal, for example, and asserted at the “L” level. The command latch enable signal (CLE) makes it possible to latch a command output from the NAND PHY 30 to the NAND device 20 to a command register in the NAND device 20. The address latch enable signal (ALE) makes it possible to latch an address output from the NAND PHY 30 to the NAND device 20 to an address register in the NAND device 20. The command latch enable signal (CLE) and the address latch enable signal (ALE) are active “H” signals, for example, and asserted at the “H” level.

The write enable signal (WEB) allows data (for example, a command or an address) to be communicated to the NAND device 20. The read enable signal (REB) makes it possible to read the data from the NAND device 20. In at least one embodiment, the read enable signal (REB) may include a read data strobe source oscillation signal which is a toggle signal which is a source of the read DQS. This will be described below. The read enable signal (REB) is a signal output so as to receive the read DQ. The write protect signal WP is a signal asserted when write and erasing is prohibited.

### Configuration of NAND Device

As illustrated in FIG. 1, the NAND device 20 includes, for example, a switching control circuit 3, a memory cell array 21, a logic control circuit 22, an input and output circuit 23, a register 24, a sequencer 25, a voltage generation circuit 26, a driver set 27, a row decoder 28, and a sense amplifier 29.

The memory cell array 21 includes a plurality of non-volatile memory cell transistors (not illustrated) associated with word lines and bit lines, and stores data in a non-volatile manner.

The logic control circuit 22 receives the chip enable signal (CEB), the command latch enable signal (CLE), the address latch enable signal (ALE), the write enable signal (WEB), the read enable signal (REB), the write protect signal (WP), and the like, from the NAND PHY 30.

In at least one embodiment, the read enable signal (REB) output from the NAND PHY 30 to the logic control circuit 22 includes a read data strobe source oscillation signal (RESS) which is a toggle signal which is a source of the read DQS (hereinafter, referred to as “source oscillation signal RESS”). The logic control circuit 22 outputs the received source oscillation signal RESS to the input and output circuit 23.

The input and output circuit 23 communicates the data signal (DQ) and the data strobe signal (DQS) between the input and output circuit 23 and the NAND PHY 30. For example, the input and output circuit 23 determines a command and an address in the data signal (DQ) based on the write enable signal (WEB), and transfers the determined command and address to the register 24. The input and output circuit 23 receives the write DQ and the write DQS from the NAND PHY 30, reads the write data by using the write DQS, and outputs the read write data to the sense amplifier 29.

The input and output circuit 23 receives the read data from the sense amplifier 29. The input and output circuit 23 uses the source oscillation signal RESS received from the logic control circuit 22 as an operation clock so as to generate the read DQ from the received read data. Further, the input and output circuit 23 uses the source oscillation signal RESS as the operation clock so as to generate the read DQS. The input and output circuit 23 outputs the generated read DQ and read DQS to the NAND PHY 30.

As illustrated in FIG. 1, the input and output circuit 23 includes a drive strength switching circuit 23a. The drive strength switching circuit 23a constitutes an output stage of the input and output circuit 23 that outputs the read DQ from the NAND device 20 to the memory controller 10. The drive strength switching circuit 23a switches a magnitude of an output current to the memory controller 10 when the read DQ is output to the memory controller 10. For example, when the transmission lines L for transmitting the read DQ between the memory controller 10 and the NAND device 20 are eight transmission lines independent from each other, the drive strength switching circuit 23a switches a magnitude of an output current when the read DQ is output to the memory controller 10 via the eight transmission lines under control of the memory controller 10. Here, a specific configuration of the drive strength switching circuit 23a for changing the output current will be described.

### Configuration of Drive Strength Switching Circuit

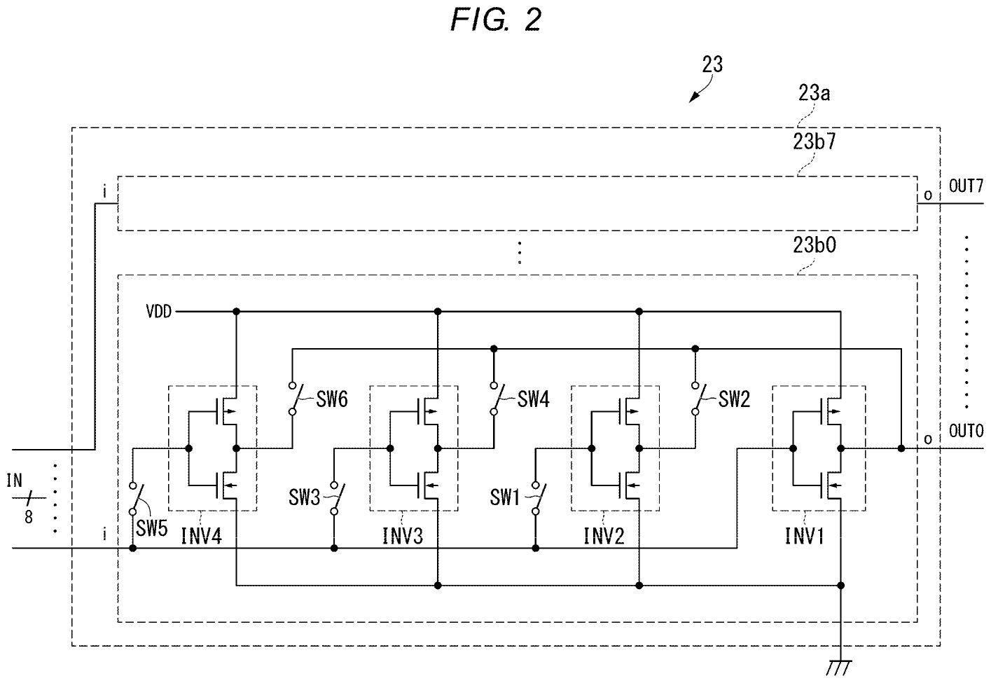

FIGS. 2 to 4 are diagrams illustrating an example of a configuration of the drive strength switching circuit 23a for changing an output current. The drive strength switching circuit 23a illustrated in FIGS. 2 to 4 includes an output transistor and a changing circuit 231 that changes a magnitude of a current of the output transistor. The memory controller 10 controls the changing circuit 231. The term of “control” includes both direct control and indirect control. That is, the memory controller 10 may control the drive strength switching circuit 23a by directly outputting a control signal to the drive strength switching circuit 23a. Further, the memory controller 10 outputs a command for controlling the drive strength switching circuit 23a to another circuit or another control device (for example, the switching control circuit 3) different from the memory controller 10, and the circuit or the control device that receives the command outputs the control signal to the drive strength switching circuit 23a so as to control the drive strength switching circuit 23a.

In at least one embodiment, the memory system 1 in which the NAND device 20 includes the switching control circuit 3 and the switching control circuit 3 controls the magnitude of the output current of the drive strength switching circuit 23a under control of the memory controller 10 will be described. Meanwhile, description of the control by the switching control circuit 3 may be omitted. For example, even when “XX controls a magnitude of an output current of the drive strength switching circuit 23a via the switching control circuit 3” is described, the XX outputs a command to the switching control circuit 3, and the switching control circuit 3 outputs the control signal to the drive strength switching circuit 23a, so that the magnitude of the output current of the drive strength switching circuit 23a is controlled.

### First Configuration Example

FIG. 2 is a diagram illustrating a first example of a configuration of the drive strength switching circuit 23a. The drive strength switching circuit 23a receives the read DQ of 8 bits by eight input terminals IN, and outputs the read DQ of 8 bits in which the magnitude of the output current is changed, from eight output terminals OUT0 to OUT7 to the memory controller 10. The drive strength switching circuit 23a includes a plurality of output circuits 23b0, 23b1, 23b2, 23b3, 23b4, 23b5, 23b6, and 23b7. Hereinafter, the output circuits 23b0, 23b1, 23b2, 23b3, 23b4, 23b5, 23b6, and 23b7 are also collectively referred to as an output circuit 23b. Each of the output circuits 23b includes an input terminal “i” and an output terminal “o”. These input terminals “i” and output terminals “o” serve as the eight input terminals IN and the eight output terminals OUT0 to OUT7 of the drive strength switching circuit 23a. Each of the output circuits 23b includes four inverters INV1, INV2, INV3, and INV4. Each of the inverters INV1, INV2, INV3, and INV4 is disposed between a power supply voltage VDD and the ground voltage.

Each of the inverters INV1, INV2, INV3, and INV4 includes, for example, an NMOS transistor and a PMOS transistor. Each of the inverters INV1, INV2, INV3, and INV4 is an example of the output transistor. An input terminal of the inverter INV1 is connected to an input terminal of the output circuit 23b0. An output terminal of the inverter INV1 is connected to an output terminal of the output circuit 23b0. An input terminal of the inverter INV2 is connected to the input terminal of the output circuit 23b0 via a switching element SW1. An output terminal of the inverter INV2 is connected to the output terminal of the output circuit 23b0 via a switching element SW2. An input terminal of the inverter INV3 is connected to the input terminal of the output circuit 23b0 via a switch element SW3. An output terminal of the inverter INV3 is connected to the output terminal of the output circuit 23b0 via a switching element SW4. An input terminal of the inverter INV4 is connected to the input terminal of the output circuit 23b0 via a switching element SW5. An output terminal of the inverter INV4 is connected to the output terminal of the output circuit 23b0 via a switching element SW6. Each of the switching elements SW1, SW2, SW3, SW4, SW5, and SW6 is an example of a circuit for changing a magnitude of a current of the output transistor. The memory controller 10 controls each of the switching elements SW1, SW2, SW3, SW4, SW5, and SW6 to be in an ON state or an OFF state. The memory controller 10 is an example of the controller.

For example, the memory controller 10 controls the switching elements SW1 and SW2 in the ON state. In this case, the inverter INV2 is connected in parallel with the inverter INV1. Further, the memory controller 10 controls the switching elements SW3 and SW4 in the ON state. In this case, the inverter INV3 is connected in parallel with the inverter INV1. Further, the memory controller 10 controls the switching elements SW5 and SW6 in the ON state. In this case, the inverter INV4 is connected in parallel with the inverter INV1. The switching elements SW1 to SW6 may be controlled so that any two or three of the inverters INV2 to INV4 are connected in parallel with the inverter INV1. That is, the memory controller 10 controls each of the switching elements SW1, SW2, SW3, SW4, SW5, and SW6 to be in the ON state or the OFF state, so that a type and the number of inverters connected in parallel may be changed. That is, the memory controller 10 controls each of the switching elements SW1, SW2, SW3, SW4, SW5, and SW6 to be in the ON state or the OFF state, so that it is possible to change a magnitude of an output current output from the output circuit 23b0. A bias is determined by connecting the inverters INV1, INV2, INV3, and INV4. That is, the switching elements SW1, SW2, SW3, SW4, SW5, and SW6 are examples of circuits for setting the bias of the output transistor. The output circuits 23b1 to 23b7 are also controlled in the same manner as the output circuit 23b0. The inverters INV1 to INV4 may have the same characteristics or different characteristics. The characteristics here include a ratio (W/L) of a gate width W to a gate length L of the transistors constituting the inverters INV1 to INV4. By changing the number of parallel inverters INV1 to INV4, the output current output from the output circuit 23b0 may be increased as compared with when only the inverter INV1 operates. Therefore, whether each of the inverters INV1 to INV4 has the same characteristic or different characteristics may be determined according to adjustment interval required by skew between pieces of the read DQ of 8 bits.

### Second Configuration Example

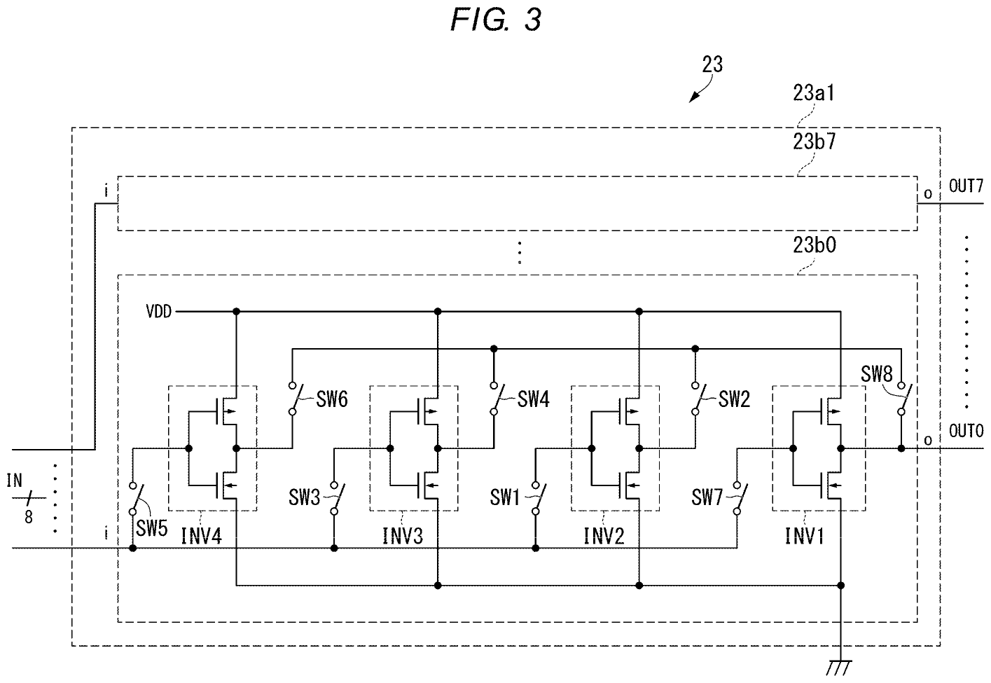

FIG. 3 is a diagram illustrating a second example of a configuration of a drive strength switching circuit 23a1. The drive strength switching circuit 23a1 receives the read DQ of 8 bits by an input terminal, and outputs the read DQ of 8 bits in which a magnitude of an output current is changed, to the memory controller 10. The drive strength switching circuit 23a1 is different from the drive strength switching circuit 23a illustrated in FIG. 2 in that, in each of the output circuits 23b, the switch SW7 is provided between an input of the output circuit 23b and an input of the inverter INV1, and the switch SW8 is provided between an output of the output circuit 23b and an output of the inverter INV1.

The input terminal of the inverter INV1 is connected to the input terminal of the output circuit 23b0 via the switching element SW7. The output terminal of the inverter INV1 is connected to the output terminal of the output circuit 23b0 via the switching element SW8. Each of the switching elements SW1, SW2, SW3, SW4, SW5, SW6, SW7, and SW8 is an example of a circuit for changing the magnitude of the current of the output transistor. The memory controller 10 controls each of the switching elements SW1, SW2, SW3, SW4, SW5, SW6, SW7, and SW8 to be in an ON state or an OFF state. The memory controller 10 is an example of the controller.

For example, the memory controller 10 controls the switching elements SW7 and SW8 in the ON state. In this case, the inverter INV1 is connected between the input terminal and the output terminal of the output circuit 23b0. Further, the memory controller 10 controls the switching elements SW1 and SW2 in the ON state. In this case, the inverter INV2 is connected between the input terminal and the output terminal of the output circuit 23b0. Further, the memory controller 10 controls the switching elements SW3 and SW4 in the ON state. In this case, the inverter INV3 is connected between the input terminal and the output terminal of the output circuit 23b0. Further, the memory controller 10 controls the switching elements SW5 and SW6 in the ON state. In this case, the inverter INV4 is connected between the input terminal and the output terminal of the output circuit 23b0. That is, the memory controller 10 controls each of the switching elements SW1, SW2, SW3, SW4, SW5, SW6, SW7, and SW8 to be in the ON state or the OFF state, so that the inverter connected between the input terminal and the output terminal of the output circuit 23b0 may be changed.

Specifically, the memory controller 10 controls each of the switching elements SW1, SW2, SW3, SW4, SW5, SW6, SW7, and SW8 to be in the ON state or the OFF state, so that it is possible to change a type and the number of inverters connected in parallel in the same manner as the first configuration example described above. Further, when the respective inverters INV1 to INV4 have different characteristics, the memory controller 10 controls each of the switching elements SW1, SW2, SW3, SW4, SW5, SW6, SW7, and SW8 to be in the ON state or the OFF state, so that it is possible to change the characteristics of the inverters. That is, the memory controller 10 controls each of the switching elements SW1, SW2, SW3, SW4, SW5, SW6, SW7, and SW8 to be in the ON state or the OFF state, so that it is possible to change a magnitude of an output current output from the output circuit 23b0. The bias is determined by connecting the inverters INV1, INV2, INV3, and INV4. That is, the switching elements SW1, SW2, SW3, SW4, SW5, SW6, SW7, and SW8 are examples of circuits for setting the bias of the output transistor. The output circuits 23b1 to 23b7 have the same manner as the output circuit 23b0. The switching elements SW1 to SW8 may be controlled so that any two or three of the inverters INV1 to INV4 are connected. The inverters INV1 to INV4 have the same characteristics and the switching elements SW1 to SW8 are controlled, so that in the drive strength switching circuit 23a1, the number of parallel inverters INV1 to INV4 may be changed.

### Third Configuration Example

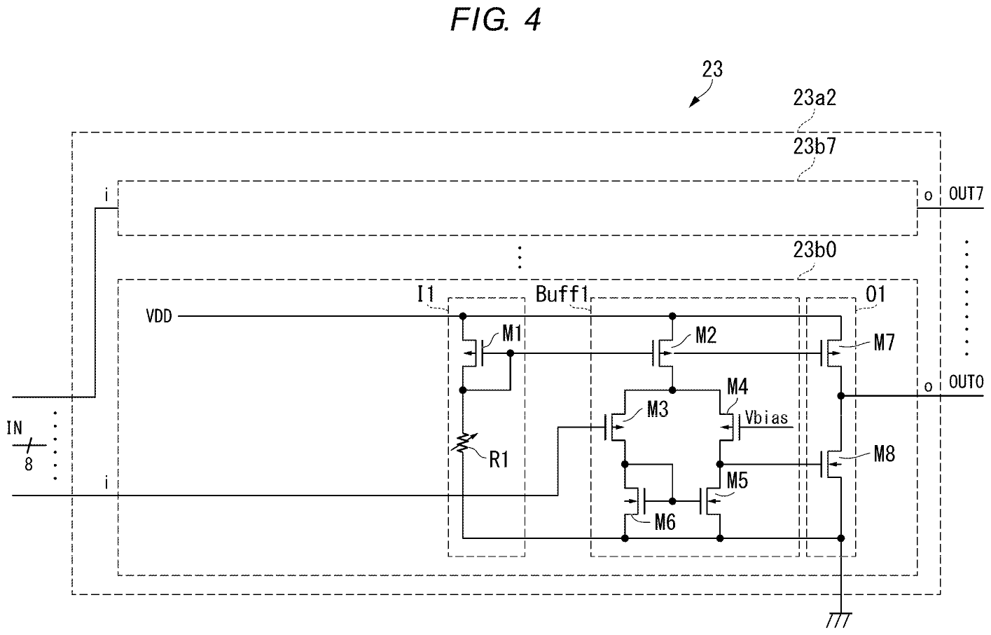

FIG. 4 is a diagram illustrating a third example of a configuration of a drive strength switching circuit 23a2. The drive strength switching circuit 23a2 includes the output circuits 23b0, 23b1, 23b2, 23b3, 23b4, 23b5, 23b6, and 23b7. Each of the output circuits 23b includes, for example, a current source I1, a buffer Buff1, and an output stage circuit O1. The current source I1, the buffer Buff1, and the output stage circuit O1 are disposed between the power supply voltage VDD and the ground voltage.

The current source I1 includes, for example, a PMOS transistor M1 and a resistor R1. The PMOS transistor M1 constitutes a current mirror together with a PMOS transistor M7, which will be described below. That is, the PMOS transistor M1 is an example of a transistor that constitutes a current mirror together with an output transistor based on a current flowing from the current source I1. Further, the PMOS transistor M1 also constitutes the current mirror with a PMOS transistor M2. The resistor R1 is a resistor of which a resistance value is changeable.

The buffer Buff1 includes the PMOS transistors M2, M3, and M4, and NMOS transistors M5 and M6. The PMOS transistor M2 mirrors the current output by the current source to set a tail current of the buffer Buff1. A gate of the PMOS transistor M2 is connected to a gate and a source of the PMOS transistor M1 through which the current output by the current source I1 flows so as to mirror the current output by the current source I1. The PMOS transistors M3 and M4 constitute an input of the buffer Buff1. The NMOS transistors M5 and M6 constitute a load of the PMOS transistors M3 and M4 constituting the input of the buffer Buff1. The buffer Buff1 is configured in this manner and a gate of the PMOS transistor M4 is biased, therefore the buffer Buff1 may be used as a buffer of a single input and a single output. A voltage of the bias is set to a voltage between the power supply voltage VDD and the ground voltage (for example, VDD/2).

The output stage circuit O1 includes the PMOS transistor M7 and the NMOS transistor M8. A drain of the PMOS transistor M7 is connected to a drain of the NMOS transistor M8. A gate of the PMOS transistor M7 is connected to the gate and the source of the PMOS transistor M1 through which the current output by the current source I1 flows so as to mirror the current output by the current source I1. The PMOS transistor M7 mirrors the current output by the current source I1 to set the bias in the output stage circuit O1. The PMOS transistor M7 is an example of the output transistor. A signal output from buffer Buff1 is input to a gate of the NMOS transistor M8. The output stage circuit O1 inverts and outputs the signal input from the buffer Buff1 from the drain of the NMOS transistor M8.

In the third configuration example, the PMOS transistor M1 is also a part of the current source I1. The circuit for changing the magnitude of the current of the output transistor includes the current source I1. Further, the memory controller 10 controls the magnitude of the current output by the current source I1. The memory controller 10 is an example of the controller. Specifically, the memory controller 10 controls the magnitude of the current output by the current source I1 by changing the resistance value of the resistor R1.

Referring again to FIG. 1, the description will be continued. The register 24 stores a command and an address. The register 24 transfers the address to the row decoder 28 and the sense amplifier 29. The register 24 transfers the command to the sequencer 25. The sequencer 25 receives the command and controls the entire NAND device 20 according to a sequence based on the received command.

The voltage generation circuit 26 generates a voltage necessary for operations such as write, read, and erasing of data based on an instruction from the sequencer 25. The voltage generation circuit 26 supplies the generated voltage to the driver set 27. The driver set 27 includes a plurality of drivers and supplies various voltages from the voltage generation circuit 26 to the row decoder 28 and the sense amplifier 29 based on the address received from the register 24. The driver set 27 supplies various voltages to the row decoder 28, for example, based on a row address in the address.

The row decoder 28 receives the row address in the address from the register 24 and selects a memory cell of a row based on the row address. The voltage from the driver set 27 is transferred to the memory cell in the selected row via the row decoder 28.

When reading of data, the sense amplifier 29 senses the read data read from the memory cell transistor into the bit line and transfers the sensed read data to the input and output circuit 23. When writing of data, the sense amplifier 29 transfers the write data to be written to the memory cell transistor via the bit line. The sense amplifier 29 receives a column address in the address from the register 24 and outputs column data based on the column address.

The switching control circuit 3 changes the magnitude of the output current of the drive strength switching circuit 23a under the control of the memory controller 10. For example, the switching control circuit 3 receives a command from the memory controller 10 to increase the output current of the drive strength switching circuit 23a. The switching control circuit 3 outputs a control signal for increasing the output current of the drive strength switching circuit 23a to the drive strength switching circuit 23a according to the received command.

### Configuration of NAND PRY

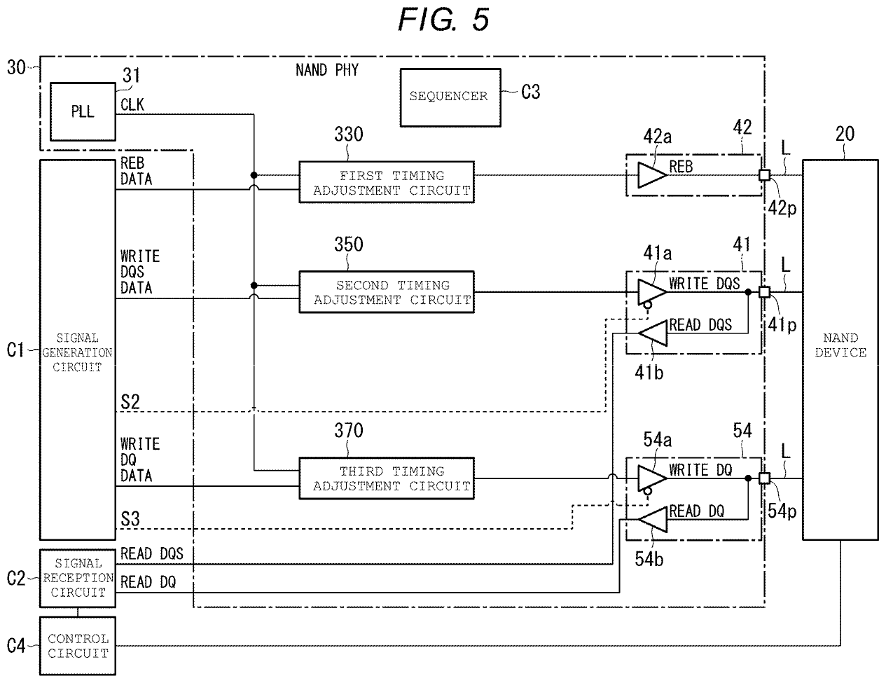

FIG. 5 is a block diagram illustrating a configuration of the NAND PHY 30. FIG. 5 illustrates a part of a circuit related to communication of a signal in the NAND PHY 30. A signal generation circuit C1, a signal reception circuit C2, and a control circuit C4 are connected to the NAND PHY 30. The signal generation circuit C1, the signal reception circuit C2, and the control circuit C4 are, for example, circuits respectively provided in the NAND I/F 16. Meanwhile, a part or all of each of the signal generation circuit C1, the signal reception circuit C2, and the control circuit C4 may be implemented by the CPU 14 executing the firmware. A part or all of each of the signal generation circuit C1, the signal reception circuit C2, and the control circuit C4 may be provided as a part of the NAND PHY 30.

The NAND PHY 30 includes, for example, a phase locked loop (PLL) circuit 31, a first timing adjustment circuit 330, a first input and output circuit 41, a second timing adjustment circuit 350, a second input and output circuit 42, a third timing adjustment circuit 370, a third input and output circuit 54, and a sequencer C3. In at least one embodiment, for convenience of explanation, a circuit including at least one of an input function and an output function of a signal is referred to as an “input and output circuit”. For example, the second input and output circuit 42 has only the output function of the signal and does not have the input function of the signal.

The PLL circuit 31 is a phase locked loop circuit, and includes an oscillator of an operation clock CLK. The PLL circuit 31 is connected to each of a first input terminal of the first timing adjustment circuit 330, a first input terminal of the second timing adjustment circuit 350, and a first input terminal of the third timing adjustment circuit 370. The PLL circuit 31 supplies the generated operation clock CLK to each of the first timing adjustment circuit 330, the second timing adjustment circuit 350, and the third timing adjustment circuit 370.

A signal indicating an output pattern of the write DQS (hereinafter, referred to as “write DQS data (or write DQS data signal)”) is input from the signal generation circuit C1 to a second input terminal of the second timing adjustment circuit 350.

A signal indicating an output pattern of the read enable signal (REB) (hereinafter, referred to as “REB data (or REB data signal)”) is input from the signal generation circuit C1 to a second input terminal of the first timing adjustment circuit 330.

A signal indicating an output pattern of the write DQ (hereinafter, referred to as “write DQ data (or write DQ data signal)”) is input from the signal generation circuit C1 to a second input terminal of the third timing adjustment circuit 370.

Each of the first timing adjustment circuit 330, the second timing adjustment circuit 350, and the third timing adjustment circuit 370 generates a signal obtained by adjusting a timing, a delay amount, and a duty ratio of a signal input from the signal generation circuit C1, and output the generated signal, based on the operation clock CLK input from the PLL circuit 31.

Specifically, the first timing adjustment circuit 330 receives the REB data from the signal generation circuit C1 and generates the read enable signal (REB) including the source oscillation signal RESS, based on the REB data and the operation clock CLK. The read enable signal (REB) is a signal obtained by adjusting a timing, a delay amount, and a duty ratio with respect to the REB data. The first timing adjustment circuit 330 outputs the generated read enable signal (REB) to the second input and output circuit 42. The read enable signal (REB) is output to a driver 42a of the second input and output circuit 42, as will be described below.

The second timing adjustment circuit 350 and the third timing adjustment circuit 370 have the same configuration as the first timing adjustment circuit 330. Therefore, in the above description of the adjustment by the first timing adjustment circuit 330, the REB data is replaced with the write DQS data and the read enable signal (REB) is replaced with the write DQS, so that the timing adjustment of the signal by the second timing adjustment circuit 350 may be considered in the same manner as the timing adjustment by the first timing adjustment circuit 330. Further, in the above description of the adjustment by the first timing adjustment circuit 330, the REB data is replaced with the write DQ data and the read enable signal (REB) is replaced with the write DQ, so that the timing adjustment of the signal by the third timing adjustment circuit 370 may be considered in the same manner as the timing adjustment by the first timing adjustment circuit 330. The write DQS is delayed to adjust skew of the write DQS with respect to the write DQ. An output of the second timing adjustment circuit 350 is connected to an input of a driver 41a of the first input and output circuit 41, which will be described below. Further, an output of the third timing adjustment circuit 370 is connected to an input of a driver 54a of the third input and output circuit 54, which will be described below. The first timing adjustment circuit 330, the second timing adjustment circuit 350, and the third timing adjustment circuit 370 may have different configurations. Further, the third timing adjustment circuit 370 may not adjust the duty of the input signal (the write DQ).

The first input and output circuit 41 includes, for example, a first terminal 41p, the driver 41a, and a receiver 41b. The first terminal 41p is, for example, a terminal for connecting the NAND FHY 30 and the outside, and is connected to the NAND device 20 via the transmission line L. The driver 41a and the receiver 41b share the first terminal 41p.

The driver 41a outputs a signal (the write DQS) input to the first input and output circuit 41, to the NAND device 20 via the first terminal 41p and the transmission line L. For example, a write DQS output enable signal (hereinafter, referred to as a “control signal S2”) from the signal generation circuit C1 is input to a control terminal of the driver 41a. When the control signal S2 is at the “L” level, the driver 41a can output the signal (the write DQS) input from the second timing adjustment circuit 350 to the first input and output circuit 41, to the NAND device 20. On the other hand, the driver 41a reduces an output of the signal input to the first input and output circuit 41 when the control signal S2 is at the “H” level.

The receiver 41b receives a signal (the read DQS) input from the NAND device 20 to the first input and output circuit 41 via the transmission line L and the first terminal 41p. That is, the write DQS and the read DQS are communicated via the same transmission line L and the same first terminal 41p. The receiver 41b outputs the received read DQS to the signal reception circuit C2.

The second input and output circuit 42 includes, for example, a second terminal 42p and the driver 42a. The second terminal 42p is, for example, a terminal for connecting the NAND PHY 30 and the outside, and is connected to the NAND device 20 via the transmission line L. The driver 42a outputs a signal (the read enable signal (REB)) input to the second input and output circuit 42, to the NAND device 20 via the second terminal 42p and the transmission line L.

The third input and output circuit 54 includes, for example, a third terminal 54p, the driver 54a, and a receiver 54b. The third terminal 54p is a terminal for connecting the NAND PHY 30 and the outside, and is connected to the NAND device 20 via the transmission line L. The driver 54a and the receiver 54b share the third terminal 54p.

The driver 54a outputs a signal (the write DQ) input to the third input and output circuit 54, to the NAND device 20 via the third terminal 54p and the transmission line L. For example, a write DQ output enable signal (hereinafter, referred to as a “control signal S3”) from the signal generation circuit C1 is input to the control terminal of the driver 54a. When the control signal S3 is at the “L” level, the driver 54a can output the signal input from the third timing adjustment circuit 370 to the third input and output circuit 54, to the NAND device 20. On the other hand, the driver 54a reduces an output of the signal input from the third timing adjustment circuit 370 to the third input and output circuit 54 when the control signal S3 is at the “H” level.

The receiver 54b receives a signal (the read DQ) input from the NAND device 20 to the third input and output circuit 54 via the transmission line L and the third terminal 54p. That is, the write DQ and the read DQ are communicated via the same transmission line L and the same third terminal 54p. The receiver 54b outputs the received read DQ to the signal reception circuit C2.

The signal reception circuit C2 receives the read DQS from the first input and output circuit 41. The signal reception circuit C2 receives the read DQ from the third input and output circuit 54. The signal reception circuit C2 reads read data from the read DQ, based on the read DQS. Further, the signal reception circuit C2 outputs the received read DQS and read DQ to the control circuit C4.

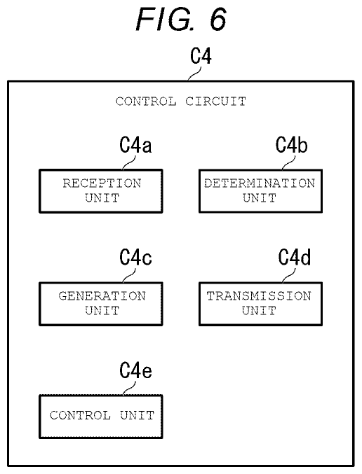

The control circuit C4 outputs a command for causing the NAND device 20 to change an output current of the drive strength switching circuit 23a, based on the read DQS and the eight read DQs received by the signal reception circuit C2. Here, a configuration of the control circuit C4 will be described with reference to FIG. 6. FIG. 6 is a diagram illustrating an example of the configuration of the control circuit C4. As illustrated in FIG. 6, the control circuit C4 includes a reception unit C4a, a determination unit C4b, a generation unit C4c, a transmission unit C4d, and a control unit C4e.

The reception unit C4a receives the read DQS and the eight read DQs from the signal reception circuit C2. For example, the reception unit C4a receives the read DQS and the read DQ when the source oscillation signal RESS is gradually delayed in the NAND device 20 (that is, when the read DQS is gradually delayed) from the signal reception circuit C2.

The determination unit C4b estimates delay times of the eight read DQs with respect to the read DQS received by the reception unit C4a, and determines whether or not a time tDVW (data valid window), which will be described below, is equal to or longer than a particular time (an example of a threshold value). The time tDVW is an example of a data valid window. The time tDVW is a time that serves as a guide for whether or not a flip-flop circuit used in a storage circuit or the like may correctly receive data and generate an output signal. Details of this determination will be described below.

When the determination unit C4b determines that the time tDVW is less than the particular time, the generation unit C4c generates a command for increasing an output current of the output circuit 23b that outputs the signal of the read DQ having the longest delay time with respect to the read DQS, among the eight read DQs. The generation unit C4c outputs the generated command to the control unit C4e. As a result, the time tDVW related to the read DQ having the longest delay time with respect to the read DQS may be lengthened.

The transmission unit C4d is a processing unit that transmits data to the NAND device 20. The control unit C4e outputs the command generated by the generation unit C4c to the NAND device 20 via the transmission unit C4d.

### Write Operation and Read Operation

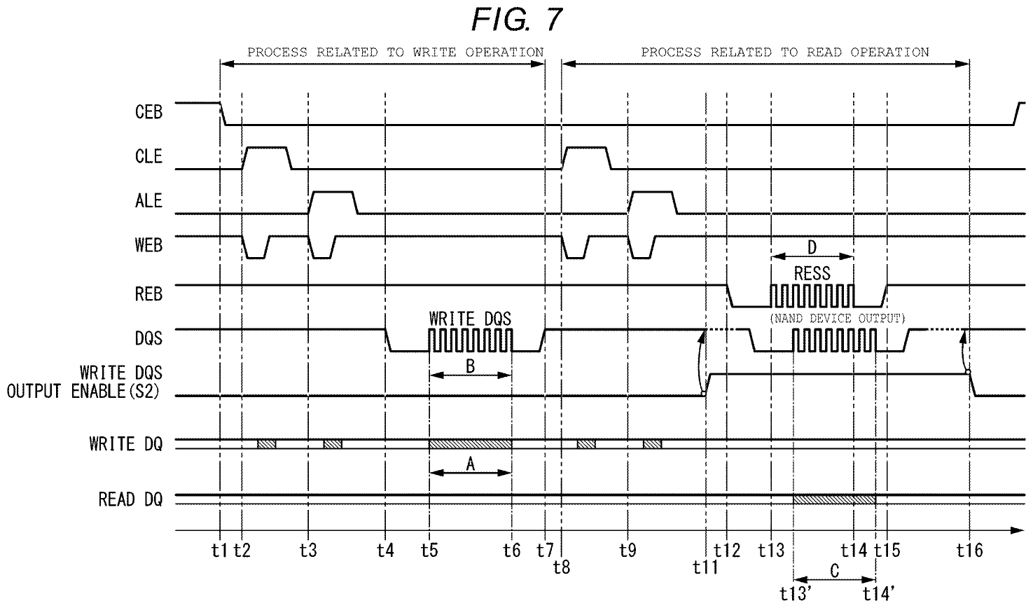

FIG. 7 is a timing chart illustrating an operation of the memory system 1. First, write of data to the NAND device 20 will be described. In the following description, it is assumed that a time elapses in an order of time points t1, t2, . . . , and tN (N is any natural number).

At the time point t1, the signal generation circuit C1 shifts the chip enable signal (CEB) related to the NAND device 20 to be accessed from the “H” level to the “L” level. As a result, the chip enable signal (CEB) is asserted, and the NAND device 20 to be accessed is in a state of being selected.

Next, the signal generation circuit C1 shifts the command latch enable signal (CLE) from the “L” level to the “H” level at the time point t2, and shifts the write enable signal (WEB) from the “H” level to the “L” level. As a result, the command latch enable signal (CLE) and the write enable signal (WEB) are asserted. The signal generation circuit C1 shifts the write enable signal (WEB) from the “L” level to the “H” level. In parallel with this operation, the signal generation circuit C1 transmits a write command for instructing the write of the data, to the NAND device 20 by the write DQ via the NAND PHY 30. The signal generation circuit C1 returns the command latch enable signal (CLE) to the “L” level after transmitting the write command.

Next, the signal generation circuit C1 shifts the address latch enable signal (ALE) from the “L” level to the “H” level at the time point t3, and shifts the write enable signal (WEB) from the “H” level to the “L” level. As a result, the address latch enable signal (ALE) and the write enable signal (WEB) are asserted. The signal generation circuit C1 shifts the write enable signal (WEB) from the “L” level to the “H” level. In parallel with this operation, the signal generation circuit C1 transmits a write destination address of the data, to the NAND device 20 by the write DQ via the NAND PHY 30. The signal generation circuit C1 returns the address latch enable signal (ALE) to the “L” level after transmitting the write destination address.

Next, the signal generation circuit C1 shifts the write DQS data input to a first signal path 30a, from the “H” level to the “L” level at the time point t4. The write DQS data from the signal generation circuit C1 is input to the second timing adjustment circuit 350. The second timing adjustment circuit 350 generates the write DQS which is a toggle signal, based on the input write DQS data and the operation clock CLK, from the time point t5 to the time point t6, and outputs the generated write DQS.

A timing, a delay amount, and a duty ratio of the write DQS from the second timing adjustment circuit 350 are adjusted. The write DQS passing through the second timing adjustment circuit 350 is input to the first input and output circuit 41. The driver 41a of the first input and output circuit 41 is supplied with the write DQS output enable signal (the control signal S2) at the “L” level at which the signal output from the signal generation circuit C1 is permitted. As a result, the write DQS input to the first input and output circuit 41 is output from the first terminal 41p to the NAND device 20.

On the other hand, the signal generation circuit C1 inputs the write data to the third timing adjustment circuit 370. The third timing adjustment circuit 370 generates the write DQ, based on the input write data and the operation clock CLK. The write DQ from the third timing adjustment circuit 370 is input to the third input and output circuit 54. The driver 54a of the third input and output circuit 54 is supplied with the write DQ output enable signal (the control signal S3) at the “L” level at which the signal output from the signal generation circuit C1 is permitted. As a result, the write DQ input to the third input and output circuit 54 is output from the third terminal 54p to the NAND device 20.

After that, the signal generation circuit C1 shifts the write DQS data input to the first signal path 30a, from the “L” level to the “H” level at the time point t7. As a result, a series of operations related to the write of the data is completed.

Next, read of data from the NAND device 20 will be described. The example illustrated in FIG. 7 illustrates a case where the NAND device 20 selected in the write operation of the data continues to be a read target for the data. The example illustrated in FIG. 7 is an example in which the write enable signal (WEB) is also used for transmitting a command and an address related to a read operation of the data. The arrows in FIG. 7 indicate that a state of the driver 41a of the first input and output circuit 41 is switched by the control signal S2 at the time points t11 and t16.

The signal generation circuit C1 shifts the command latch enable signal (CLE) from the “L” level to the “H” level at the time point t8, and shifts the write enable signal (WEB) from the “H” level to the “L” level. As a result, the command latch enable signal (CLE) and the write enable signal (WEB) are asserted. The signal generation circuit C1 shifts the write enable signal (WEB) from the “L” level to the “H” level. In parallel with this operation, the signal generation circuit C1 transmits a read command for instructing the read of the data to the NAND device 20 by the write DQ via the NAND PRY 30. The signal generation circuit C1 returns the command latch enable signal (CLE) to the “L” level after transmitting the read command.

Next, the signal generation circuit C1 shifts the address latch enable signal (ALE) from the “L” level to the “H” level at the time point t9, and shifts the write enable signal (WEB) from the “H” level to the “L” level. As a result, the address latch enable signal (ALE) and the write enable signal (WEB) are asserted. The signal generation circuit C1 shifts the write enable signal (WEB) from the “L” level to the “H” level. In parallel with this operation, the signal generation circuit C1 transmits a read destination address of the data, to the NAND device 20 by the write DQ via the NAND PHY 30. The signal generation circuit C1 returns the address latch enable signal (ALE) to the “L” level after transmitting the read destination address.

Next, the signal generation circuit C1 shifts the write DQS output enable signal (the control signal S2) from the “L” level to the “H” level at the time point t11, and maintains the “H” level until the time point t16. That is, by setting the control signal S2 in a negate state, it is possible to reduce the output of the signal from the first input and output circuit 41. As a result, it is possible for the first input and output circuit 41 to receive the read DQS.

Next, the signal generation circuit C1 shifts the REB data input to the second signal path 30b, from the “H” level to the “L” level at the time point t12. As a result, the NAND device 20 is notified that the read operation is in a ready state. The REB data from the signal generation circuit C1 is input to the first timing adjustment circuit 330. The first timing adjustment circuit 330 generates the source oscillation signal RESS, which is a toggle signal, based on the input REB data and the operation clock CLK from the time point t13 to the time point t14.

A timing, a delay amount, and a duty ratio of the generated source oscillation signal RESS are adjusted in the first timing adjustment circuit 330. The source oscillation signal RESS output by the first timing adjustment circuit 330 is input to the second input and output circuit 42. As a result, the source oscillation signal RESS input to the second input and output circuit 42 is output from the second terminal 42p to the NAND device 20.

According to this operation, the NAND device 20 outputs the read DQS with respect to the first terminal 41p of the NAND PHY 30, and outputs the read DQ with respect to the third terminal 54p of the NAND PHY 30. As illustrated in FIG. 7, the read DQS is a signal slightly delayed with respect to the source oscillation signal RESS. The first input and output circuit 41 outputs the read DQS input to the first terminal 41p, to the signal reception circuit C2. The third input and output circuit 54 outputs the read DQ input to the third terminal 54p, to the signal reception circuit C2 The signal reception circuit C2 reads the read data based on the input read DQ and read DQS.

After that, the signal generation circuit C1 shifts the REB data input to the second signal path 30b, from the “L” level to the “H” level at the time point t15. According to this operation, the read DQS shifts from the “L” level to the “H” level. As a result, the output operation of the signal from the NAND PHY 30 related to the read of the data is completed.

When the read operation of the data described above is performed, the signal generation circuit C1 maintains the write DQS data at the “H” level. At the time point t16, the signal generation circuit C1 shifts the write DQS data maintained at the “H” level to the “L” level.

### Operation of Reducing Delay Variations Between Read DQs

At a time for shipment of the memory system 1, there are inspection items related to delay variations among a plurality of read DQs. In this inspection item, for example, it is determined whether or not the time tDVW is equal to or longer than a particular time. When it is determined that the time tDVW is equal to or longer than the particular time, the inspection item passes, and when it is determined that the time tDVW is less than the particular time, the inspection item fails. An operation for reducing the delay variations among the plurality of read DQs illustrated below is performed with respect to, for example, the memory system 1 which fails for the inspection item. As a result, the memory system 1 which fails may pass the inspection item, and a yield of the memory system 1 may be improved. For example, known data (for example, data of which “H” level is read at a correct timing) is written in advance in the NAND device 20. After that, a timing of the read DQS is shifted by changing a delay time of the source oscillation signal RESS, and a range of a timing of the read DQ at which the known data can be read correctly is specified. By executing such an operation, the delay variations among the plurality of read DQs are obtained.

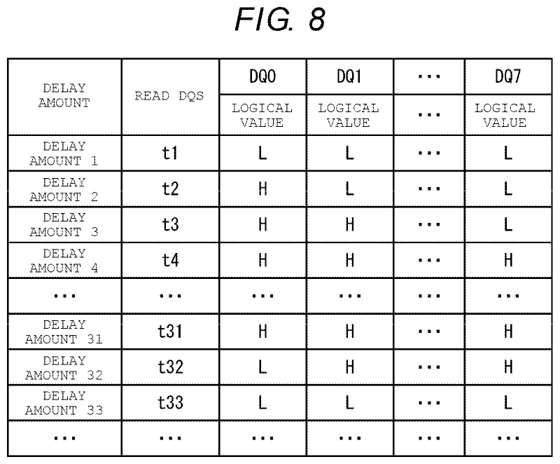

The control circuit C4 performs adjustment on the NAND device 20 to gradually increase the delay amount of the source oscillation signal RESS. The delay amount of read DQS changes in proportion with respect to the delay amount of source oscillation signal RESS. Each time the control circuit C4 causes the NAND device 20 to increase the delay amount of the source oscillation signal RESS, the signal reception circuit C2 receives the read DQS from the first input and output circuit 41, and receives the read DQ from the third input and output circuit 54. Each time the signal reception circuit C2 receives the read DQS and the read DQ, the signal reception circuit C2 outputs the received read DQS and read DQ to the control circuit C4. FIG. 8 is an example of the read DQS and the read DQ received by the signal reception circuit C2. A logical value obtained by reading each bit of the read DQ received by the signal reception circuit C2 is obtained, with respect to each timing (described as t1, t2, t3, . . . in FIG. 8) of the read DQS corresponding to each delay amount of the source oscillation signal RESS (described as delay amounts 1, 2, 3, . . . in FIG. 8).

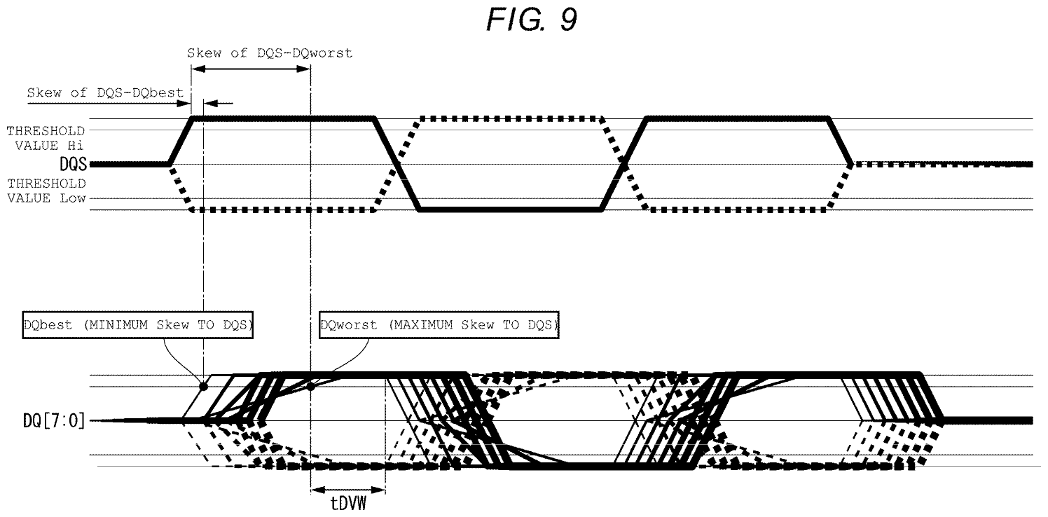

FIG. 9 is a diagram illustrating an example of waveforms of the read DQS and the read DQ. FIG. 9 illustrates the read DQ (DQbest), which is the minimum skew with respect to a rise timing of the read DQS, the minimum skew (Skew of DQS-DQbest) of the read DQ, the read DQ (DQworst), which is the maximum skew with respect to the rise timing of the read DQS, the maximum skew (Skew of DQS-DQworst) of the read DQ, and the time tDVW. The control circuit C4 obtains the read DQ as the DQbest, the Skew of DQS-DQbest which is the minimum skew by the read DQ, the read DQ as the DQ worst, the Skew of DQS-DQworst which is the maximum skew by the read DQ, and the time tDVW, from the read DQS and the read DQ illustrated in FIG. 8. The waveform illustrated in FIG. 9 is a waveform obtained by using, for example, an oscilloscope. When the memory system 1 has a function capable of analyzing this waveform, the read DQ which is the minimum skew with respect to the rise timing of the read DQS, the minimum skew of the read DQ, the read DQ which is the maximum skew with respect to the rise timing of the read DQS, the maximum skew of the read DQ, and the time tDVW may be calculated, by performing an image analysis process on the obtained waveform, for example.

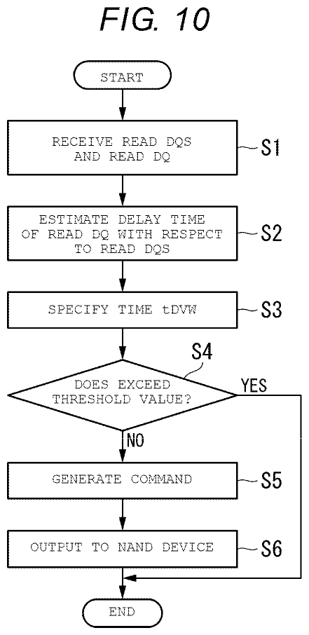

Here, an operation of reducing delay variations among the plurality of read DQs will be described below with reference to FIG. 10. FIG. 10 is a flowchart illustrating an operation of reducing delay variations between the read DQs. The reception unit C4a receives the read DQS and the read DQ from the signal reception circuit C2 (S1). The reception unit C4a outputs the received read DQS and read DQ to the determination unit C4b.

The determination unit C4b receives the read DQS and the read DQ from the reception unit C4a. The determination unit C4b estimates a delay time of the read DQ with respect to the received read DQS (S2). For example, it is assumed that the read DQS and read DQ received by the determination unit C4b are as illustrated in FIG. 8. In this case, the determination unit C4b determines a logical value of the read DQ obtained at each time in ascending order from the time point t1, which is the earliest time of the read DQS. The determination unit C4b determines that there is no read DQ at the “H” level at the time point t1. Next, the determination unit C4b specifies that a DQ0 at a logical value of the “H” level is the read DQ (DQbest) having the minimum skew with respect to the rise timing of the read DQS at the time point t2. Further, the determination unit C4b specifies the minimum skew (Skew of DQS−DQbest) as (t2−t1). Further, the determination unit C4b specifies DQ7 having the logical value of “H” level at the time point t4, which is the latest time of the read DQS, as the read DQ (DQworst) having the maximum skew with respect to the rise timing of the read DQS. Further, the determination unit C4b specifies the maximum skew (Skew of DQS−DQworst) as (t4−t1). Further, the determination unit C4b specifies the time tDVW as (t31−t4), from the time point t31 and the time point t4 of the “H” level immediately before an output of the DQ0 is at the “L” level (S3).

The determination unit C4b compares the specified time tDVW with a threshold value (an example of a particular time). For example, the threshold value may be an inspection reference for the time tDVW at the time for shipment. The determination unit C4b determines whether or not the specified time tDVW exceeds the threshold value, based on the comparison result (S4).

When it is determined that the specified time tDVW exceeds the threshold value (YES in S4), the process is completed. When it is determined that the specified time tDVW does not exceed the threshold value (NO in S4), the generation unit C4c generates a command for increasing the output current of an output circuit 23b which outputs the read DQ having the longest delay time (the read DQ of the DQ7 in the examples of FIGS. 8 and 9) with respect to the read DQS (S5). This is for the purpose of lengthening the time tDVW by shortening the delay time of the read DQ output by the output circuit 23b of a target. The generation unit C4c outputs the generated command to the control unit C4e. The control unit C4e outputs the command generated by the generation unit C4c to the NAND device 20 via the transmission unit C4d (S6).

In the NAND device 20, the switching control circuit 3 receives the command from the control circuit C4. The switching control circuit 3 controls the output circuit 23b indicated by the received command to increase the output current. The control circuit C4 re-processes S1 in the flowchart illustrated in FIG. 10. The process illustrated in FIG. 10 is repeated until it is determined that the specified time tDVW exceeds the threshold value in the process in S4, or the new time tDVW specified in the process in S3 is not improved from the previously specified time tDVW.

### Advantages

According to such a configuration, it is possible to reduce timing variations among the plurality of read DQs. As a result, it is possible to improve reliability of read data. Further, since the time tDVW may be lengthened, accurate data may be read at a higher speed. That is, it is possible to improve a quality of a signal at a time of reading.

Some modification examples according to at least one embodiment will be described below.

### First Modification Example

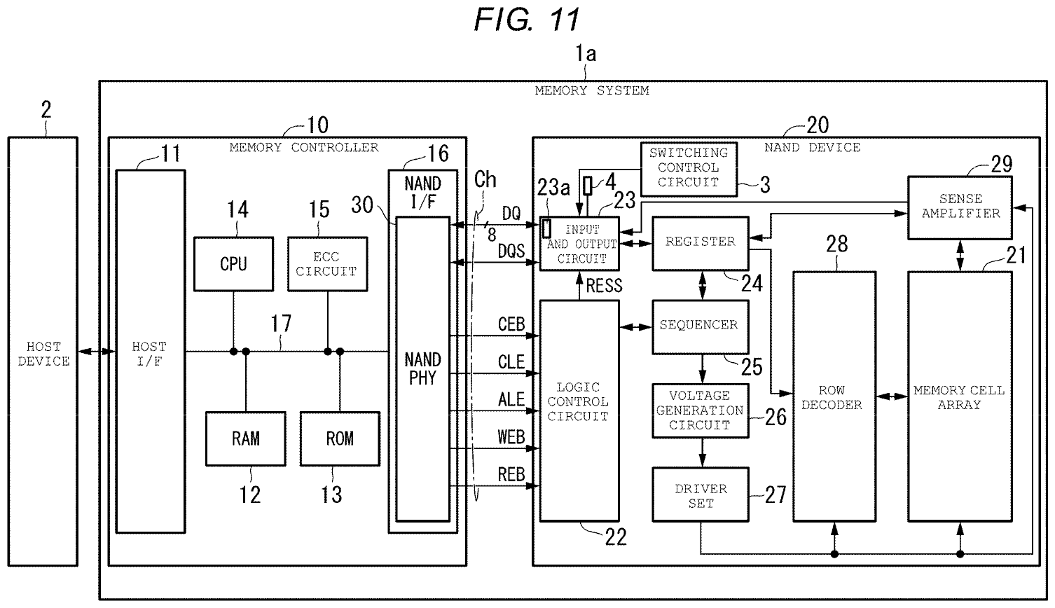

FIG. 11 is a block diagram illustrating a configuration of a memory system 1a according to a first modification example. The memory system 1a according to the first modification example includes a temperature sensor 4. For example, the temperature sensor 4 is provided inside the NAND device 20 and is connected to, for example, the input and output circuit 23. The temperature sensor 4 may be provided inside any one of the memory controller 10 and the memory system 1a. The memory system 1 according to at least one embodiment described above is a system that determines whether or not the time tDVW exceeds the threshold value at the time of shipment for the memory system 1, and changes the output current of the output circuit 23b so as to adjust a read timing of the read DQ when the time tDVW does not exceed the threshold value. On the other hand, the memory system 1a according to the first modification example is a system that changes the output current of the output circuit 23b based on a temperature measured by the temperature sensor 4.

For example, a temperature range in which influence of a temperature change on the time tDVW is large is set in advance. The memory controller 10 monitors the temperature measured by the temperature sensor 4 via, for example, the input and output circuit 23. When the memory controller 10 determines that the monitored temperature is within a preset temperature range, the control circuit C4 performs adjustment to gradually increase the delay amount of the source oscillation signal RESS. This adjustment may be performed by performing the process described with reference to FIG. 10. The process has the same manner as that of the memory system 1 according to at least one embodiment described above, except that the temperature measured by the temperature sensor 4 is a trigger of the process of the memory system 1a.

According to such a configuration, it is possible to reduce the timing variations among the plurality of read DQs even when the time tDVW fluctuates due to the temperature change. As a result, it is possible to improve reliability of read data. Further, since the time tDVW may be lengthened, accurate data may be read at a higher speed. That is, it is possible to improve a quality of a signal at a time of reading.

### Second Modification Example

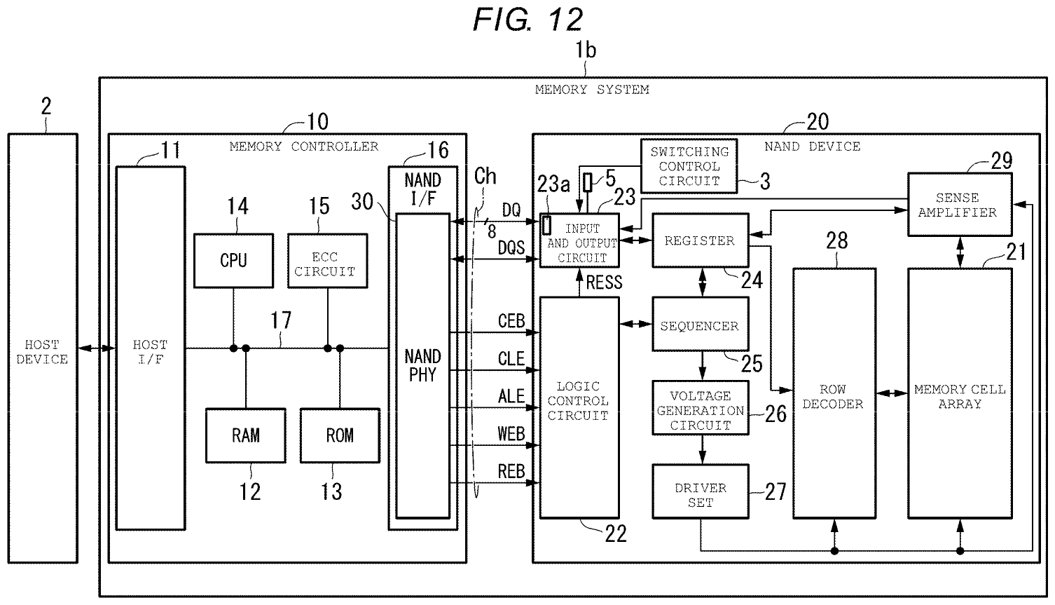

FIG. 12 is a block diagram illustrating a configuration of a memory system 1b according to a second modification example. The memory system 1b according to the second modification example includes a voltage detection circuit 5. The voltage detection circuit 5 is provided inside the NAND device 20, and is connected to, for example, the input and output circuit 23. The voltage detection circuit 5 may be provided inside any one of the memory controller 10 and the memory system 1b. For example, the voltage detection circuit 5 uses an element that generates a fixed voltage value with respect to a reference voltage to measure a voltage value as a target. The voltage detection circuit 5 sets a certain voltage value, and outputs a detection signal when the voltage value drops below the certain voltage value. The memory controller 10 monitors the detection signal output by the voltage detection circuit 5 via, for example, the input and output circuit 23. When it is determined that the voltage detection circuit 5 outputs the detection signal, the memory controller 10 cause the control circuit C4 to perform adjustment to gradually increase the delay amount of the source oscillation signal RESS. This adjustment may be performed by performing the process described with reference to FIG. 10. The process has the same manner as that of the memory system 1 and the memory system 1a according to the embodiments described above, except that the voltage detection circuit 5 outputs the detection signal as a trigger for the process of the memory system 1b.

### Third Modification Example

In at least one embodiment described above, the control circuit C4 controls the output current of the output circuit 23b. Meanwhile, when the adjusted output current of the output circuit 23b is not changed after being set once, for example, the switching elements SW1 to SW8 and the resistor R1 illustrated in any one of FIGS. 2 to 4 may be structurally determined to be connected to the output transistor by cutting a wiring using a laser trimming technology.

According to such a configuration, it is not necessary to constantly operate the control circuit C4. As a result, it becomes possible to reduce power consumption of the memory system 1 after shipment.

According to at least one embodiment described above, a memory system includes a semiconductor storage device and a controller. The semiconductor storage device includes an output transistor and a circuit of changing a magnitude of a current of the output transistor. The controller controls the circuit. According to such a configuration, it is possible to improve quality of a signal.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system comprising:
a semiconductor storage device including an output transistor and a circuit configured to change a magnitude of a current of the output transistor; and
a controller configured to receive a signal output from the semiconductor storage device via the output transistor, and control the circuit based on a level of the received signal.

2. The memory system according to claim 1,
wherein the circuit is configured to set a bias of the output transistor, and
the controller is configured to control the circuit to control the bias.

3. The memory system according to claim 1,
wherein the controller is configured to:
receive a strobe signal and a plurality of data signals corresponding to the strobe signal,
detect a plurality of delay differences between the strobe signal and each of the plurality of data signals, and
control a circuit which outputs a data signal having a largest delay difference among the plurality of delay differences to increase a magnitude of the current, when a data valid window obtained from the plurality of delay differences is less than a threshold value.

4. The memory system according to claim 1, further comprising:
a temperature sensor configured to measure a temperature,
wherein the controller is configured to control the circuit based on the measured temperature.

5. The memory system according to claim 1, further comprising:
a detection circuit configured to measure a voltage applied to the semiconductor storage device,
wherein the controller is configured to control the circuit based on the measured voltage.

6. The memory system according to claim 1, wherein the semiconductor storage device includes a NAND memory.

7. The memory system according to claim 1, wherein the output transistor includes at least one inverter.

8. The memory system according to claim 1, wherein the semiconductor storage device includes a plurality of output transistors, each of the output transistors including an inverter.

9. The memory system according to claim 1, wherein the circuit includes at least one switching element.

10. The memory system of claim 1, wherein the semiconductor storage device includes a plurality of circuits, each of the plurality of circuits including at least one switching element.

11. A control method of a memory system that includes a semiconductor storage device having an output transistor whose current magnitude is changeable, the method comprising:
receiving a signal output from the semiconductor storage device via the output transistor; and
controlling the magnitude of the current of the output transistor based on a level of the received signal.

12. The method according to claim 11,
wherein the semiconductor storage device includes a circuit configured to set a bias of the output transistor, and
the method further comprising controlling the circuit to control the bias.

13. The method according to claim 11, further comprising:
receiving a strobe signal and a plurality of data signals corresponding to the strobe signal;
detecting a plurality of delay differences between the strobe signal and each of the plurality of data signals; and
controlling a circuit which outputs a data signal having a largest delay difference among the plurality of delay differences to increase a magnitude of the current, when a data valid window obtained from the plurality of delay differences is less than a threshold value.

14. The method according to claim 11, further comprising:
measuring a temperature of the semiconductor storage device; and
controlling the magnitude of the current of the output transistor based on the measured temperature.

15. The method according to claim 11, further comprising:
measuring a voltage applied to the semiconductor storage device; and
controlling the magnitude of the current of the output transistor based on the measured voltage.

16. The method of claim 11, wherein the semiconductor storage device includes a plurality of output transistors,
wherein the receiving includes receiving a signal output from each of the plurality of output transistors.

17. The memory system of claim 16, wherein the semiconductor storage device includes a plurality of circuits, each of the plurality of circuits including at least one switching element,
the method further comprising controlling each of the circuits to control a bias of each of the output transistors.
